(19) United States
(12) Patent Application Publication
(10) Pub. No.: US 2006/0237166 A1
(43) Pub. Date: Oct. 26, 2006

(54) High Efficiency Fluid Heat Exchanger and Method of Manufacture

(76) Inventors: Robert W. Otey, Litchfield, NH (US); David A. Kaminski, Dunbarton, NH (US)

Correspondence Address: MESMER & DELEAULT, PLLC, 41 BROOK STREET, MANCHESTER, NH, 03104, US

(21) Appl. No.: 11/379,619

(22) Filed: Apr. 21, 2006

Related U.S. Application Data
(60) Provisional application No. 60/594,606, filed on Apr. 22, 2005.

(51) Int. Cl. H05K 7/20

(52) U.S. Cl. 165/80.4; 165/170; 29/890.03

(57) ABSTRACT

A fluid heat exchanger has a housing having a thermally conductive base, a plurality of fin members connected to the base in a parallel, spaced relationship, a heat exchanger fluid inlet on one side of the plurality of fin members, and a heat exchanger fluid outlet on the opposite side of the plurality of fin members. The plurality of fin members each have a plurality of passageways and are arranged in the housing so that the passageways of one fin member are offset from the passageways of adjacent fin members.

This application claims the benefit of US Provisional Patent Application No. 60/594,606, filed Apr. 22, 2005.

### BACKGROUND OF THE INVENTION

1. Field of the Invention

The present invention relates to heat exchangers. Particularly, the present relates to fluid-based heat exchangers.

2. Description of the Prior Art

Heat exchangers have been used in numerous applications and include air-cooled as well as liquid cooled heat exchangers. Liquid cooled heat exchangers typically include a manifold having a maze configuration where the fluid follows a continuous, tortuous path from the inlet port to the outlet port. This causes the fluid to flow over a greater distance within the manifold causing the fluid to remain in contact with the heating or cooling surface of the exchanger for a longer period of time. However, prior art heat exchangers are expensive to make and can be relatively large.

Compact heat exchangers have also been developed that are more concerned with size than ease of manufacture and assembly. Compact heat exchangers are characterized by their high “area density” which means that they have a high ratio of heat transfer surface to heat exchanger volume. Such heat exchangers are typically used to cool (or heat) process fluids.

One well known but “expensive to manufacture” type of heat exchanger is the tube and shell heat exchanger. These types of heat exchangers have an exterior tubular shell through which runs a number of longitudinally-extending smaller diameter tubes carrying one or more fluids. Other fluids, with which heat is to be exchanged, typically pass transversely across the heat exchanger such that heat is exchanged through the tube walls. A large number of tubes may be needed and they each have to be individually and accurately secured into a header plate at each end of the shell. High quality tubing then needs to be assembled into the plates and brazed or welded or mechanically-expanded into position. As the tubes are reduced in diameter to increase surfaces available for heat transfer, performance and compactness, the more difficult and expensive such configurations become to manufacture.

A second known type of heat exchanger is the primary plate/secondary plate type exchanger in which a stack of plates is assembled. The stack has primary plates that directly separate two different fluid streams and secondary plates between adjacent primary plates. The secondary plates act as fins which add to the strength of the structure and may be provided with perforations to provide additional flow paths for the fluids. These compact heat exchangers tend to have a large number of components assembled in intricate patterns. One such heat exchanger is disclosed.

U.S. Pat. No. 6,695,044 (2004, Symonds) discloses a compact heat exchanger having a bonded stack of plates. The stack of plates includes at least one group of plates having one or more perforated plates sandwiched between a pair of primary separator plates. Each perforated plate has perforations arranged in rows across the plate in a first direction with a land between each adjacent pair of perforations in a row and with ribs between adjacent rows. The lands form barriers to flow in a first direction across the plate and the ribs form barriers to flow in a second direction across the plate. The second direction is normal to the first direction. The ribs have vents through a portion of their thickness. The vents extend from one side of a rib to the other side in a second direction whereby the flow channels are provided through the vents and the flow channels lying between each adjacent pair of lands provide a flow passage to cross the plates in the second direction. The passageways in the group of plates are separated from passageways in any adjacent group of plates by one of the separator plates.

U.S. Pat. No. 5,193,611 (1993, Hesselgreaves) discloses a heat exchanger having a plurality of fluid pathways in which at least some are defined between surfaces of unperforated primary plates. Between the primary plates are at least two secondary perforated plates extending along the fluid pathway with perforations in adjacent plates being staggered. Adjacent secondary and primary sheets are in contact such that conducting pathways are formed extending between the two primary surfaces while areas of secondary plates not in contact with other secondary plates constitute secondary surfaces.

Therefore, what is needed is a heat exchanger that is inexpensive to manufacture. What is also needed is a heat exchanger that is easy to assemble. What is further needed is a heat exchanger that can be easily coupled to other components in a system that requires a compact heat exchanger.

### SUMMARY OF THE INVENTION

It is an object of the present invention to provide a heat exchanger that is inexpensive to make. It is another object of the present invention to provide a heat exchanger that is easy to assemble. It is a further object of the present invention to provide a heat exchanger that can be easily coupled to other components in a heat exchanging system. It is still another object of the present invention to provide a heat exchanger that provides high heat exchange in a compact device.

The present invention achieves these and other objectives by providing a high efficiency, low cost fluid heat exchanger. The heat exchanger includes a housing having at least a portion of a housing wall made of a thermally conductive material, a fluid inlet and a fluid outlet, and a plurality of heat conducting fin members inside the housing thermally connected to the thermally conductive wall portion of the housing. The fin members have a plurality of passageways through the fin members. The fin members are connected to the thermally conductive wall portion of the housing in a parallel, spaced relationship and arranged so that the plurality of passageways of one fin member is offset from the plurality of passageways of an adjacent fin member. Each fin member is made of a thermally conducting material.

The preferred embodiment of the heat exchanger of the present invention includes a housing with a base and a cover that is preferably made by extruding base and cover stock to the desired size for a particular application. The fin members may be made from blank stock or sheet, or they may be extruded. If made from blank stock or sheet, they are preferably made by milling, sawing or drilling a plurality of the desired openings/passageways into the blank stock or sheet. Once the stock sheet contains the desired number of passageways, the stock sheet is cut to the desired thickness of a fin member. On the other hand, the stock or sheet may be extruded with the plurality of openings/passageways and then cut to obtain the desired thickness of a fin member. The fin members may also be individually extruded to the desired length, width and thickness along with the desired plurality of openings/passageways.

The fin members are connected to the base, preferably by brazing, in order to provide a good thermally conductive bond between the fin members and the base. The fin members are arranged so that the passageways are in an alternating configuration so that the flow of fluid through the housing is continuously altered resulting in a relatively large surface area within a relatively small heat exchanger. The alternating configuration of the fin members causes the fluid to turbulently flow through the heat exchanger while exposing a greater portion of the fluid volume to the thermally conductive fin members leading to a more efficient heating or cooling effect.

The cover is sealingly connected to the base, preferably by brazing, and the desired fluid inlet and fluid outlet fittings are attached to the housing so that the fluid inlet and fluid outlet are positioned relative to the fin members to cause the flow of the heat exchange fluid to flow through and across each fin members in sequential order. Because the present invention can be assembled using a minimum number of different components, the present invention provides a heat exchanger that is inexpensive to make, easy to assembly, easy to customize depending on the size of the heat exchanger required, and has a good ratio of heat exchange surface area to the size of the heat exchanger.

### BRIEF DESCRIPTION OF THE DRAWINGS

FIG. 1 is a perspective, open view of one embodiment of the heat exchanger of the present invention showing the plurality of the spaced-apart fin members.

FIG. 2 is a perspective view of one embodiment of the fin member block showing circularly shaped passageways.

FIG. 3 is a perspective view of another embodiment of the fin member block showing a plurality of groove passageways.

FIG. 4 is a top view of the plurality of fin members of the present invention showing the offset nature of the passageways and the illustrated path of fluid flow of the heat exchanger fluid.

### DETAILED DESCRIPTION OF THE PREFERRED EMBODIMENT

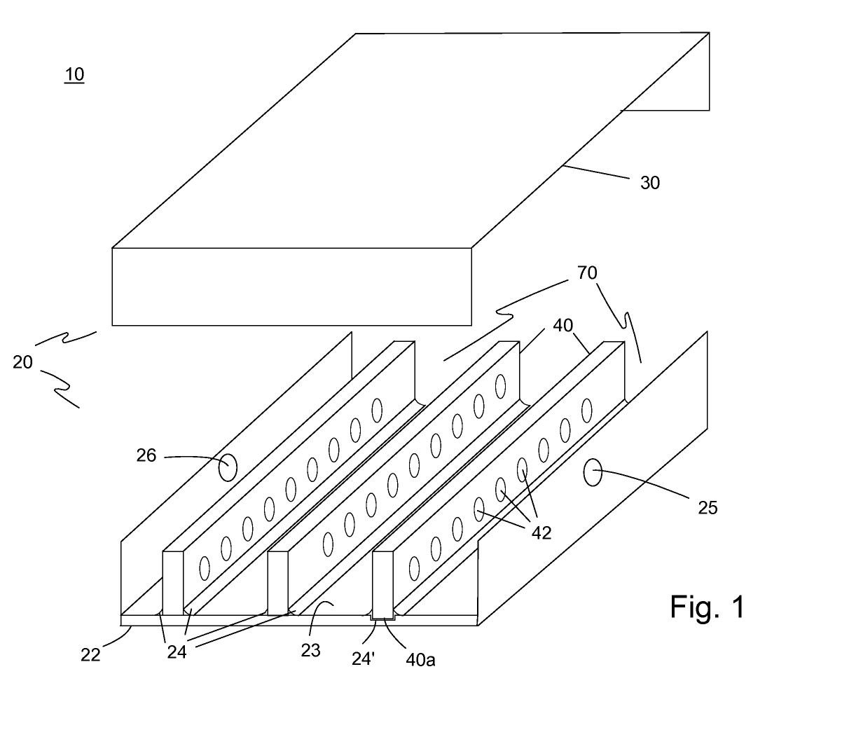

The preferred embodiment(s) of the present invention is illustrated in FIGS. 1-4. FIG. 1 shows one embodiment of a heat exchanger 10 of the present invention in a separated view. Heat exchanger 10 includes a housing 20 with a fluid inlet 25 and a fluid outlet 26 and a plurality of fin members 40 enclosed within housing 20. Housing 20 has a thermally conductive portion 22 to which the plurality of fin members 40 are thermally connected.

In the preferred embodiment, housing 20 has a base 22 and a cover 30. Base 22 is made of a thermally conductive material and is the thermally conductive portion. Base 22 optionally and preferably includes a plurality of ribs 24 or grooves 24′ along an inside surface 23. It should be understood that both the base and cover may be made of thermally conductive material.

The plurality of fin members 40, which are made of a thermally conductive material, are thermally connected along a base edge 40a to the inside surface 23 of base 22 where each fin member 40 is spaced from an adjacent fin member 40. Each fin member 40 in the preferred embodiment illustrated in FIG. 1 is preferably a piece of elongated, thermally conductive, sheet material sized to provide a close fitting contact along its remaining sides with the walls of housing 20. In other words, each fin member 40 of the preferred embodiment has a length equal to the width of the inside of housing 20 and a height equal to the inside height of housing 20.

Where the optional ribs 24 are used, each pair of ribs 24 is sized to receive and support one of the plurality of fin members 40. Where the optional grooves 24′ are used, only one fin member 40 occupies one groove 24′. Each fin member 40 includes a plurality of passageways 42. The size and spacing of each fin member 40 creates a plurality of chambers 70 within housing 20 through which a heat exchanging fluid moves between fluid inlet 25 and fluid outlet 26.

As illustrated in FIG. 1, each fin member 40 is arranged so that the plurality of passageways 42 in one fin member 40 is offset from the plurality of passageways 42 of an adjacent fin member. Offsetting the passageways 42 of adjacent fin members 40 causes turbulent flow within the heat exchanging fluid. The surface of base 22 to which the plurality of fin members 40 is connected is made of a thermally conductive material, as are the plurality of fin members 40. Fin members 40 are preferably thermally connected to inside surface 23 by brazing.

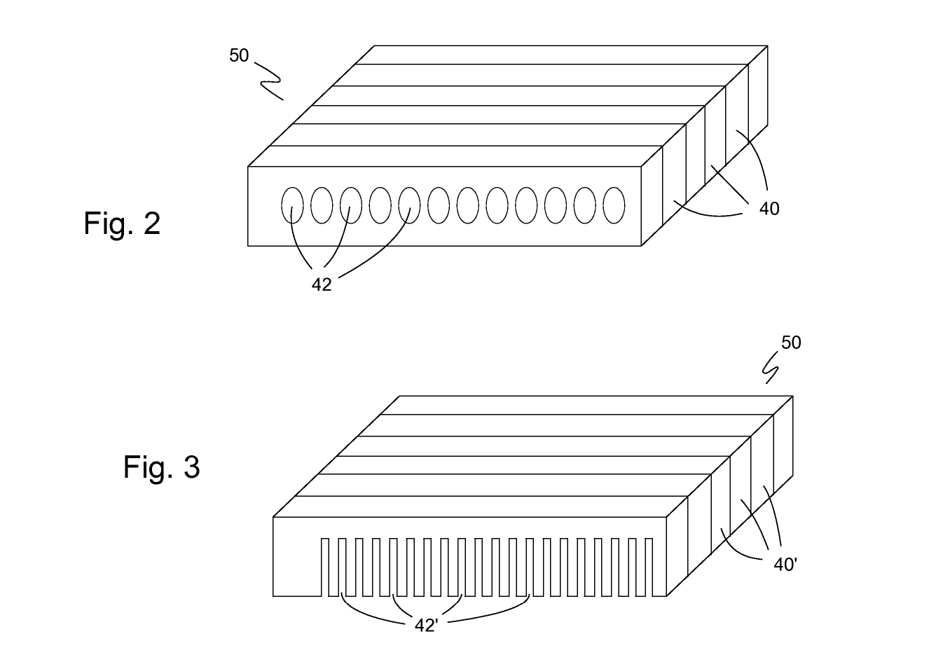

Turning now to FIG. 2, there is illustrated the fin member block or sheet 50. A plurality of passageways 42 is formed through the fin member block 50. Fin member block 50 is then cut into individual fin members 40. It should be noted that the plurality of passageways 42 are made closer to one end of fin member block 50 than the opposite end. Although this configuration is not required for making the present invention function, it is important for economic reasons. By forming the passageways 42 into fin member block 50, the cost to make and assemble heat exchanger 10 is reduced. Every other fin member 40 of a predetermined number of fin members 40 selected for a particular heat exchanger 10 is rotated around its short central axis. This causes each successive plurality of passageways 42 to be offset from the plurality of passageways 42 of adjacent fin members 40. It should be understood that fin member block or sheet 50 may be (1) extruded with the desired plurality of passageways 42 and then cut to form individual fin members 40, or (2) extruded then the plurality of passageways 42 formed into the fin member block 50 prior to cutting individual fin members 40. On the other hand, each fin member 40 may be extruded with the desired plurality of passageways 42 or they may be extruded bars into which the plurality of passageways 42 is then formed. It should be understood that the components may be made by any method known to one of ordinary skill in the art including, but not limited to, casting, extrusion, forging, machining, etc.

FIG. 3 illustrates another embodiment of fin members 40. In this embodiment, a plurality of groove passageways or notches 42′ is made into one surface of the fin member block 50 along its entire length or width. The plurality of groove passageways or notches 42′ creates the passageways through which the heat exchanger fluid will pass. Like the embodiment in FIG. 2, the fin member block 50 containing the plurality of groove passageways 42′ are cut into a plurality of fin members 40′ having a plurality of notches 42′ along one edge or may be extruded, or extruded and cut, or made using any combination of methods. The plurality of fin members 40′ are also assembled such that the grooves 42′ are not aligned with the grooves 42′ of adjacent fin members 40′. Like the embodiment in FIG. 2, every other fin member 40′ of a predetermined number of fin members 40′ selected for a particular heat exchanger 1 0 is rotated around its short central axis. This causes each successive plurality of passageways 42′ to be offset from the plurality of passageways 42′ of adjacent fin members 40′.

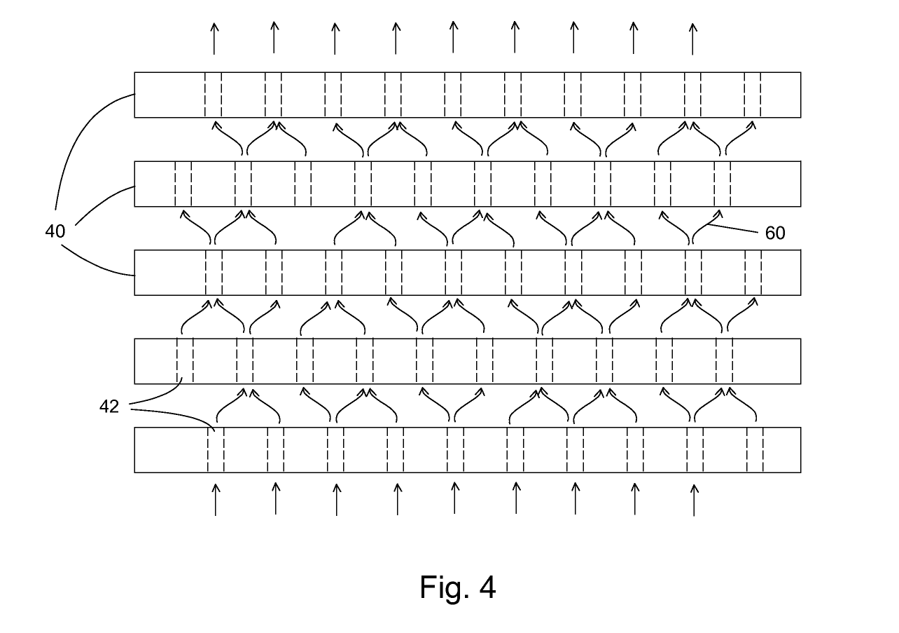

Turning now to FIG. 4, there is illustrated a representation of the flow pattern of a heat exchanger fluid through the heat exchanger 1 0 of the present invention. The plurality of arrows 60 indicate the path of the heat exchanger fluid as it progresses from an inlet side to an outlet side of the heat exchanger 1 0. As illustrated in FIG. 4, the plurality of passageways 42 of one fin member 40 is offset from the plurality of passageways 42 of adjacent fin members 40. This causes the flow of the heat exchanger fluid to mix, which causes the heat within the fluid to mix and become more evenly distributed for subsequent transfer to fin members 40 downstream of the flow. Where each fin member 40 is thermally connected to the inside surface 23 of base 22, the heat absorbed by each fin member 40 is conducted to base 22. Base 22 may optionally be in contact with another heat exchange surface, a thermoelectric module, a plurality of air-cooled fins, or other heat exchange system. Base 22 may also have a plurality of heat exchanging structures integrally formed onto the outside surface of base 22.

The preferred method of making heat exchanger 10 is to extrude all of the components, base 22, cover 30 and the plurality of fin members 40. Each of the plurality of fin members 40 are then attached to the inside surface 23 of base 22, preferably by brazing. Cover 30 is then assembled to base 22 preferably by brazing forming a watertight compartment that contains the plurality of spaced-apart fin members 40 whose plurality of passageways 42 are offset with adjacent fin members 40. It should be understood that the fin members 40 do not have to be rectangular as illustrated but may be any shape such that the circumferential edge of the fin member are in substantially close contact with the inside surfaces of housing 20, except that one edge of the fin member must be thermally connected to the thermally conductive portion of housing 20.

Although the preferred embodiments of the present invention have been described herein, the above description is merely illustrative. Further modification of the invention herein disclosed will occur to those skilled in the respective arts and all such modifications are deemed to be within the scope of the invention as defined by the appended claims.

What is claimed is:

1. A high efficiency fluid heat exchanger comprising:
a housing having a thermally conductive wall portion, a fluid inlet and a fluid outlet; and
a plurality of fin members thermally connected to said thermally conductive portion, said plurality of fin members being parallel and in a spaced relationship to each other, said plurality of fin members having a plurality of passageways therethrough wherein said plurality of passageways of one fin member is offset from said plurality of passageways of adjacent fin members;
wherein said plurality of fin members are positioned between said fluid inlet and said fluid outlet to cause the heat exchange fluid to flow across said plurality of fin members.

2. The fluid heat exchanger of claim 1 wherein said plurality of passageways are openings through said plurality of fin members.

3. The fluid heat exchanger of claim 1 wherein said plurality of passageways are a plurality of notches.

4. The fluid heat exchanger of claim 1 wherein said thermally conductive wall portion has a plurality of ribs wherein each pair of ribs is sized to receive and support one of said plurality of fin members.

5. The fluid heat exchanger of claim 1 wherein said thermally conductive wall portion has a plurality of grooves sized to receive and support one of said plurality of fin members.

6. The fluid heat exchanger of claim 1 wherein said thermally conductive wall portion is a base of said housing.

7. The fluid heat exchanger of claim 1 wherein said housing has a thermally conductive base and a cover wherein said plurality of fin members are thermally connected to said base.

8. A method of making a high efficiency fluid heat exchanger comprising:
forming a housing having a thermally conductive wall portion, a fluid inlet and a fluid outlet; and
thermally connecting a plurality of fin members to said thermally conductive wall portion in a parallel, spaced relationship, each fin member of said plurality of fin members having a plurality of passageways across and through said fin member, said plurality of fin members being spaced apart and having said plurality of passageways of one fin member offset from said plurality of passageways of an adjacent fin member, said plurality of fin members being positioned within said housing to cause the heat exchange fluid to flow through and across each of said plurality of fin members in sequential order.

9. The method of claim 8 wherein said housing forming step further includes forming a base and a cover, said base being said thermally conductive wall portion.

10. The method of claim 9 wherein said housing forming step further includes forming a plurality of spaced grooves sized to receive one of said plurality of fin members.

11. The method claim 9 wherein said housing forming step further includes forming a plurality of paired ribs wherein each of said pair of ribs are spaced to receive and support one of said plurality of fin members.

12. The method of claim 9 further comprising forming said passageways through each of said plurality of fin members.

13. The method of claim 9 further comprising forming said plurality of fin members by obtaining a block of thermally conductive material, forming a plurality of passageways through said block in one direction, and cutting said block in an opposite direction to form individual fin members.

14. The method of claim 9 further comprising forming said plurality of fin members by obtaining a block of thermally conductive material, forming a pluralilty of grooves along one side of said block in one direction, and cutting said block in an opposite direction to form individual fin members having a plurality of notches.
